(19) United States
(12) Patent Application Publication
(10) Pub. No.: US 2024/0303390 A1
(43) Pub. Date: Sep. 12, 2024

(54) A COMPUTER-IMPLEMENTED METHOD FOR THE SIMULATION OF AN ENERGY-FILTERED ION IMPLANTATION (EFII) USING AN ION TUNNEL

(71) Applicant: mi2-factory GmbH, Jena (DE)

(72) Inventors: Florian Krippendorf, Jena (DE); Constantin Csato, Jena (DE)

(73) Assignee: mi2-factory GmbH, Jena (DE)

(21) Appl. No.: 18/547,768

(22) PCT Filed: Feb. 22, 2022
(86) PCT No.: PCT/EP2022/054400

§ 371 Date: Aug. 24, 2023

(30) Foreign Application Priority Data
Feb. 24, 2021 (LU) LU 102559

(51) Int. Cl. G06F 30/20; H01J 37/05; H01J 37/317

(52) U.S. Cl. CPC G06F 30/20; H01J 37/05; H01J 37/3171

(57) ABSTRACT

A computer-implemented method for the simulation of an energy-filtered ion implantation (EFII), including: Determining at least one part of an energy filter; determining a simulation area in a substrate; Defining an ion tunnel for receiving ions directed from an ion beam source; implementing the determined at least one part of the energy filter, the ion beam source, the determined simulation area in the substrate, and the defined ion tunnel in a simulation environment; determining a minimum distance between the implemented at least one part of the energy filter and the implemented substrate for enabling a desired degree of lateral homogenization of the energy distribution in a doping depth profile of the implemented substrate; and defining a total simulation volume.

### CROSS-REFERENCE TO RELATED APPLICATIONS

This application is a U.S. National Stage Application of, and claims the benefit of, International PCT Application Number PCT/EP2022/054400, filed on Feb. 22, 2022, which claims the benefit of and priority to Luxembourg Patent Application LU 102559, filed on 24 Feb. 2021. The entire disclosure of Luxembourg Patent Application LU 102559 is hereby incorporated by reference.

### TECHNICAL FIELD

The present disclosure relates a computer-implemented method for the simulation of an energy-filtered ion implantation using an ion tunnel.

### BACKGROUND

In commercially oriented micro technical production processes, masked and/or non-masked doping elements are to be introduced by means of ion implantation into materials, such as semiconductors (silicon, silicon carbide, gallium nitride) or optical materials (glass, LiNbO3, PMMA), with predefined depth profiles in the depth range from a few nanometers up to a plurality of 10 micrometers.

Ion implantation is a method to achieve doping or production of defect profiles in a material, such as semiconductor material or an optical material, with predefined depth profiles in the depth range of a few nanometers to a plurality of tens of micrometers. Examples of such semiconductor materials include, but are not limited to silicon, silicon carbide, and gallium nitride. Examples of such optical materials include, but are not limited to, LiNbO₃, glass and PMMA.

There is a need to produce depth profiles by ion implantation which have a wider depth distribution than that of a doping concentration peak or defect concentration peak obtainable by monoenergetic ion irradiation or to produce doping or defect depth profiles which cannot be produced by one or a few simple monoenergetic implantations. The doping concentration peak can often be represented approximately by a Gaussian distribution or more precisely by a Pearson distribution. However, there are also deviations from such distributions, especially when so-called channeling effects are present in the crystalline material. Related art methods produce the depth profile using a structured energy filter in which the energy of a monoenergetic ion beam is modified as the monoenergetic ion beam passes through a micro-structured energy filter component. The resulting energy distribution leads to a creation of the depth profile ions in the target material. This is described, for example, in European Patent no. EP 0 014 516 B1. An energy filter for tailoring depth profiles in a semiconductor doping application is know from CSATO CONSTANTIN ET AL (“Energy filter for tailoring depth profiles in semiconductor doping application”, NUCLEAR INSTRUMENTS & METHODS IN PHYSICS RESEARCH. SECTION B: BEAM INTERACTIONS WITH MATERIALS AND ATOMS, vol. 365, pages 182-186, XP029313812, ISSN: 0168-583X, DOI: 10.1016/J.NIMB.2015.07.102). Ion beam irradiation of nanostructures is disclosed from BORSCHEL C ET AL (“Ion beam irradiation of nanostructures A 3D Monte Carlo simulation code”, NUCLEAR INSTRUMENTS & METHODS IN PHYSICS RESEARCH. SECTION B: BEAM INTERACTIONS WITH MATERIALS AND ATOMS, vol. 269, no. 19, pages 2133-2138, XP028266956, ISSN: 0168-583X, DOI: 10.1016/J.NIMB.2011.07.004).

An example of such an ion implantation device 20 is shown in FIG. 1 in which an ion beam 10 impacts a structured energy filter 25. The ion beam source 5 could also be a cyclotron, an rf-linear accelerator, an electrostatic tandem accelerator, or a single-ended-electrostatic accelerator. In other aspects, the energy of the ion beam source 5 is between 0.5 and 3.0 MeV/nucleon or in one aspect between 1.0 and 2.0 MeV/nucleon. In one specific aspect, the ion beam source produces an ion beam 10 with an energy of between 1.3 and 1.7 MeV/nucleon. The total energy of the ion beam 10 is between 1 and 50 MeV, in one aspect, between 4 and 40 MeV, and in a further aspect between 8 and 30 MeV. The frequency of the ion beam 10 could be between 1 Hz and 2kH, for example between 3 Hz and 500 Hz and, in one aspect, between 7 Hz and 200 Hz. The ion beam 10 could also be a continuous ion beam 10. Examples of the ions in the ion beam 10 include, but are not limited to aluminum, nitrogen, hydrogen, helium, boron, phosphorous, carbon, arsenic, and vanadium.

FIG. 1 shows the basic principle of an energy filter. A monoenergetic ion beam is modified in its energy as the monoenergetic ion beam passes through the micro-structured energy filter component, depending on the point of entry. The resulting energy distribution of the ions leads to a modification of the depth profile of the implanted substance in the substrate matrix.

FIG. 1 shows that the energy filter 25 is made from a membrane having a triangular cross-sectional form on the right-hand side, but this type of cross-sectional form is not limiting of the present disclosure and other cross-sectional forms could be used. The upper ion beam 10-1 passes through the energy filter 25 with little reduction in energy because the area 25ₘᵢₙ through which the upper ion beam 10-1 passes through the energy filter 25 is a minimum thickness of the membrane in the energy filter 25. In other words, if the energy of the upper ion beam 10-1 on the left-hand side is E1 then the energy of the upper ion beam 10-1 will have substantially the same value E1 on the right-hand side (with only a small energy loss due stopping power of the membrane which leads to absorption of at least some of the energy of the ion beam 10 in the membrane).

On the other hand, the lower ion beam 10-2 passes through an area 25ₘₐₓ in which the membrane of the energy filter 25 is at its thickest. The energy E2 of the lower ion beam 10-2 on the left-hand side is absorbed substantially by the energy filter 25 and thus the energy of the lower ion beam 10-2 on the right-hand side is reduced and is lower than the energy of the upper ion beam, i.e., E1>E2. The result is that the more energetic upper ion beam 10-1 is able to penetrate to a greater depth in the substrate material 30 than the less energetic lower ion beam 10-2. This results in a differential depth profile in the substrate material 30, which is, for example, part of a semiconductor wafer.

This depth profile is shown on the right-hand side of the FIG. 1. The solid rectangular area shows that the ions penetrate the substrate material to a depth between d1 and d2. However, the horizontal profile shape is a special case, which is, for example, obtained if all energies of the ions are geometrically equally taken into account and if the material of the energy filter and the substrate is the same. The Gaussian curve shows the approximate depth profile without an energy filter 25 and having a maximum value at a depth of d3. It will be appreciated that the depth d3 is larger than the depth d2 since some of the energy of the ion beam 10-1 is absorbed in the energy filter 25.

For typical ion species (N, Al, B, P) in the energy range from 1 MeV up to some tens of MeV (e.g., 40 MeV) it can be observed that low energy ions tend to have a large scattering angle and high energy ions tend to have a small scattering angle. The reason for this different scattering behavior is the energy dependence of the underlying stopping mechanisms. Ions with high kinetic energy preferentially lose their energy by so-called electronic stopping, i.e., excitations of the electron system of the substrate. This usually results in only small directional deviation, i.e., small scattering angles. Ions with low kinetic energy preferentially lose their energy by elastic collisions with the atoms of the substrate, so-called nuclear stopping. This results in large angle scattering.

For a static implantation arrangement (i.e., filter and substrate are not moved with respect to each other), which is one aspect for the simulation of doping depth profiles, the distance between filter and substrate plays the decisive role. As can be seen in FIGS. 6A and 6B, if the distance 50 is chosen too small, transfer of the filter structure into the implanted doping depth profile may occur due to the low scattering of high-energy ions. In other words, to avoid this effect, the profiles generated by single filter unit cell or single filter element must overlap sufficiently so that a desired degree of lateral homogenization is achieved.

In summary for a given ion species, a given initial ion energy, a given filter design and a given substrate material and a given filter-substrate distance a certain energy distribution and angular distribution of the filter transmitted ions will be generated.

In the related art there are a number of principles for the fabrication of the energy filter 25. Typically, the energy filter 25 will be made from bulk material with the surface of the energy filter 25 etched to produce the desired pattern, such as the triangular cross-sectional pattern shown from FIG. 1. In German Patent No. DE 10 2016 106 119 B4 an energy filter was described which was manufactured from layers of materials which had different ion beam energy reduction characteristics. The depth profile resulting from the energy filter depends on the structure of the layers of the material as well as on the structure of the surface.

A further construction principle is shown in the German Patent application DE 10 2019 120 623.5, in which the energy filter comprises spaced micro-structured layers which are connected together by vertical walls.

The maximum power from the ion beam 10 that can be absorbed through the energy filter 25 depends on three factors: the effective cooling mechanism of the energy filter 25, the thermo-mechanical properties of the membrane from which the energy filter 25 is made, as well as the choice of material from which the energy filter 25 is made. In a typical ion implantation process around 50% of the power is absorbed in the energy filter 25, but this can rise to 80% depending on the process conditions and filter geometry.

An example of the energy filter is shown in FIG. 2A in which the energy filter 25 is made of a triangular structured membrane mounted in a frame 27. In one non-limiting example, the energy filter 25 can be made from a single piece of material, for example, silicon on insulator which comprises an insulating layer silicon dioxide layer 22 having, for example a thickness of 0.2-1 μm sandwiched between a silicon layer 21 (of typical thickness between 2 and 20 μm, but up to 200 μm) and bulk silicon 23 (around 400 μm thick). The structured membrane is made, for example, from silicon, but could also be made from silicon carbide or another silicon-based or carbon-based material or a ceramic.

In order to optimize the wafer throughput in the ion implantation process for a given ion current for the ion beam 10 and thus use the ion beam 10 efficiently, it is one aspect to only irradiate the membrane of the energy filter 25 and not the frame 27 in which the membrane is held in place. It is likely that at least part of the frame 27 will also be irradiated by the ion beam 10 and thus heat up. It is indeed possible that the frame 27 is completely irradiated. The membrane forming the energy filter 25 is heated up but has a very low thermal conductivity as the membrane is thin (i.e., between 2 μm and 20 μm, but up to 200 μm). The membranes are between 2×2 cm² and 35×35 cm² in size and correspond to the size of the target wafers. There is little thermal conduction between the membranes and the frame 27. Thus, the monolithic frame 27 does not contribute to the cooling of the membrane and the only cooling mechanism for the membrane which is relevant is the thermal radiation from the membrane.

As shown in FIG. 2B, a substrate holder 30 need not be stationary, but can optionally be provided with a device for moving the substrate 12 in x-y (in the plane perpendicular to the sheet plane). Furthermore, a wafer wheel on which the substrates 12 to be implanted are fixed and which rotates during implantation can also be considered as the substrate holder 30. It is also possible to move the substrate holder 30 in the beam direction (x-direction) of the ion beam 10 with respect to the energy filter 25. Furthermore, the substrate holder 30 may optionally be provided with heating or cooling.

FIGS. 3A and 3B show the typical installation of an energy filter 25 in a system for ion implantation for the purpose of wafer processing. FIG. 3A shows a wafer wheel 24 on which the substrates 26 to be implanted are fixed. During processing/implantation, the wafer wheel 24 is tilted upward by 90° in the direction of the ion beam 10 and set in rotation. The wafer wheel 24 is thus “written” with ions in concentric circles by the ion beam 10. In order to irradiate the entire wafer area, the wafer wheel 24 is moved vertically during processing. In FIG. 3B, a mounted energy filter 25 can be seen in the area of the beam exit. However, the installation of an energy filter 25 in a system for ion implantation for the purpose of wafer processing is not limited to a rotational setup, but also a stationary setup for ion implantation for the purpose of wafer processing is possible, as for example is shown in FIG. 2A.

The layouts or three-dimensional structures of energy filters 25 shown in FIGS. 4A to 4D illustrate the principal possibilities of using energy filters 25 to generate a large number of doping depth profiles 40. In principle, the energy filter profiles can be combined with each other to obtain new energy filter profiles and thus doping depth profiles 40.

FIGS. 4A to 4D show the schematic illustration of different doping depth profiles 40 (doping concentration as a function of depth in the substrate) for differently shaped energy filter microstructures (each shown in a side view and a top view). In FIG. 4A, a triangular prism-shaped structure is shown to produce a rectangular doping depth profile. In FIG. 4B, a smaller triangular prism-shaped structure is shown, producing a less depth-distributed rectangular doping depth profile. In FIG. 4C, a trapezoidal prism-shaped structure is shown that produces a rectangular doping depth profile with a peak at the beginning of the profile. In FIG. 4D, a pyramid-shaped structure is shown that produces a triangular doping depth profile that rises into the depth of the substrate.

Generally, one may simulate energy filtered ion implantation. However, the fundamental problem of simulating energy filtered ion implantation lies in the different geometric dimensions of the implantation structure. The energy filter structural elements are typically triangular structures, e.g., made of silicon with a height difference between minimum and maximum membrane thickness of about 1 μm over about 16 μm up to 100 μm. A plurality of such structural elements, arranged side by side, form an energy filter. The dimensions of an energy filter structural element in a direction perpendicular to the ion beam direction are also in the order of a few micrometers to a few 100 μm. For the energy filters used in practice, macroscopic dimensions of the energy filter membrane are required from 2×2 cm, over 17×17 cm up to 40×40 cm. Substrate sizes are also in this range. The distances between the energy filter and the substrate, on the other hand, are typically in the millimeter or centimeter range.

FIG. 5A shows a schematic illustration of a filter unit cell 30 of a filter structure. The energy filters 25 are constructed from single elements or single filter unit cells 30. Each unit cell 30 provides (in the simplest case) the entire energy and angular spectrum of transmitted ions. The characteristic doping depth profiles 40 of an energy-filtered ion implantation (EFII) thus result from the irradiation of a filter unit cell 30. The side-by-side arrangement of the n-unit cells 30 is merely an extension, which is necessary for the irradiation of extended substrates, see FIG. 5A. FIG. 5B shows the cross-sectional view in the y-z plane of a static irradiation situation of the energy filter 25, the ion source 5 and the substrate 26. The structures typically formed with micrometer dimensions in the y-direction become macroscopically extended energy filters, with dimensions up to 40 cm, when arranged in a side-by-side manner. The same is true for the z-direction, as can be also seen in FIG. 5B. The ions are scattered while passing through the energy filter 25. During this process, the ions experience a loss of energy due to geometry and material selection, as well as lateral scattering, resulting in a characteristic energy-angle distribution of the ions after exiting the energy filter 25.

For a static setup according to FIG. 5B, in which the energy filter 25 is arranged plane-parallel to the substrate 26 and at a sufficiently large defined distance from the substrate, a desired degree of lateral homogenization of the energy distribution of the ions in the y-z plane is achieved and thus mapping of the microstructure of the energy filter 25 to the substrate 26 is avoided, i.e., in the sense of a mathematical mapping function. FIG. 6A shows an arrangement in which an energy filter 25 is in contact with the substrate 26, so that a mapping of the energy filter 25 to the doping depth profile 40 takes place. In FIG. 6B an arrangement of the energy filter 25 and the substrate 26 with a “sufficient” distance 50 is shown, so that the doping depth profile 40 is implanted laterally (y-z plane) and homogeneously into the substrate 26 in a plane perpendicular to the ion beam direction of the ion beam 10.

FIGS. 7A to 7C show simulated 1-D (z-y integrated) doping depth profiles 40 as well as 2-D profiles in the x-y plane of the substrate 26 with a filter dimension of 1000 μm×1000 μm. The top plots in FIGS. 7A to 7C show the two-dimensional distribution of the doping concentration in the y-x plane. The corresponding lower representations in FIGS. 7A to 7C show the integral summed-up along both the y-axis and z-axis for each case.

In the following section, this irradiation arrangement of FIG. 5B will now be considered in more detail by means of an example. In particular, the dependence of the resulting energy spectrum on the design of the implantation arrangement (distance filter-substrate) is to be clarified on the basis of the implanted ion concentration as a function of the location in the substrate 26.

Initial situation: filter dimensions of the energy filter 25 are y≈1000 μm, z≈1000 μm with a plurality of unit cells (full triangular structure) arranged in a side-by-side manner, with unit cell dimensions of x=16 μm, y≈11 μm, translation symmetry in z. The implanted ion is aluminum, primary energy 12 MeV, filter material is equal to substrate material, is equal to silicon.

FIG. 7A shows the energy filter 25 and the substrate 26 spaced 20 μm apart. In FIG. 7A, the energy filter 25 and the substrate 26 are at a distance of fs=20 μm from each other. The 2-D map in the x-y plane of the substrate 26 shows a mapping of the microstructure of the energy filter 25 to the substrate 26. The lateral scattering of the ions from neighboring ones of the single cells is not sufficient to achieve a desired degree of lateral homogenization along the y-axis of the doping in the substrate 26, as shown in FIG. 6A.

FIG. 7B shows an energy filter 25 and a substrate 26 spaced 500 μm apart. In FIG. 7B, the energy filter 25 and the substrate 26 are at a distance 50 of fs=500 μm from each other. No transfer of the microstructure of the energy filter 25 to the substrate 26 can be seen. The lateral scattering of ions from neighboring single cells is sufficient to achieve a desired degree of lateral homogenization of the doping in the substrate 26. The filter-substrate spacing was correctly chosen in this case.

FIG. 7C shows the energy filter 25 and the substrate 26 at a distance of 3000 μm from each other. According to FIG. 7C, when the distance between the energy filter 25 and the substrate 26 is further increased, de-homogenization of the energy distribution of the ions in the y-z plane occurs, resulting in a gradient in the depth doping depth profile summed along the y-axis. This de-homogenization of the energy spectrum of the ions is due to the large distance between the energy filter 25 and the substrate 26, as well as the dimensions of the ion source and the energy filter 25. Both the scattering angle of the scattered ions with large scattering angle and the large filter-substrate distance result in that some of the strongly scattered ions will no longer hit the substrate 25 and are scattered past the substrate 25. The ions scattered in this way no longer hit the substrate 25 and are therefore “lost”.

In real energy-filtered irradiation, it is one aspect to achieve a laterally homogeneous concentration and energy distribution of the ions analogous to the situation shown in FIG. 7B. The desired degree of lateral homogenization of the doping depth profile as well as the preservation of the full characteristic energy spectrum is realized in practice by dynamic implantation. Here, the microstructure mapping, independent of the distance, is avoided by a relative movement from the substrate 26 to the energy filter 25. Furthermore, in practice, the loss of ions at the edge of the wafer substrate 26 is avoided by over-scanning the filtered ion beam beyond the edges of the substrate 26.

For the simulation of energy-filtered ion implantation, a static arrangement is assumed. To achieve a desired degree of lateral homogenization and avoid particle loss, the boundary condition is that the resulting energy spectrum of the simulated energy filter must be independent of the spatial coordinates y-z on the wafer. In other words, the full energy-angle spectrum of a unit cell must be found on any y-z position on the wafer.

Ion implantation is a process “composed” of a large number of individual events. One needs a large number of single ions (typically 1E12 cm-2-1E15 cm-2) in order to form typical distributions in the substrate due to statistical scattering processes. The use of Monte Carlo techniques is therefore widespread in the field of ion implantation.

Therefore, simulation methods can support or shorten development processes or facilitate the accurate design and dimensioning of processes and products. In order to be able to carry out a reasonable simulation in terms of time and cost with sufficient statistics, a method must therefore be used which takes into account the different size ratios and in this way drastically reduces the complexity and the computational effort for the simulation without loss of accuracy.

The typical dimensions of interesting simulation areas for ion implantation process simulation in semiconductor technology are perpendicular to the ion beam in the size range of a plurality of micrometers up to a plurality of millimeters or even centimeters and parallel to the ion beam (depth profile) in the range of a plurality of micrometers up to 100 micrometers. The typical resolution requirement in all directions is at least 5 or 10 nanometers. To achieve the required spatial resolution, these areas must be subdivided into a fine grid in the nanometer range and simulated with a correspondingly high number of events to resolve relevant characteristics with high event density.

It is an object of the present disclosure to provide a computer-implemented method which allows the simulation of doping depth profiles of energy filtered ion beams by means of a so-called “Monte Carlo” algorithm. In particular to provide a method for complex ion implantation processes, such as the EFII process, to be efficiently simulated using the Monte Carlo method in order to be able to reproduce the real physical process and its effects in the substrate as accurately as possible and without artifacts.

By implementing the ion implantation arrangement in a Monte Carlo simulation environment, the complex structure of such an array implies a high workload for the implementation of the involved structures. In general, the widely varying dimensions of the microscopic filter structure compared to the filter-substrate spacing results in a poor ratio of total simulation volume Sᵥ, e.g., shown in FIG. 8, to the “interesting” simulation area g. The demand for high grid and event density of the simulation area causes a high total number of simulation events in the total simulation volume Sᵥ, which can only be simulated with cost-intensive computing technology and high simulation durations.

It is an object of the present disclosure to provide a computer-implemented method for embedding the simulation of energy-filtered ion implantation into the tool landscape for technology simulation of semiconductor electronic devices (TCAD).

It is an object of the present disclosure to provide a computer-implemented method to significantly improve the efficiency of the Monte Carlo simulation of an energy-filtered implantation process, i.e., to reduce the effort for the implementation of the model, to reduce the complexity of the computer simulation and ultimately to reduce the computing time or to reduce the requirements on the performance of the computer hardware. With respect to the geometric simulation model, the present disclosure improves the ratio of the total simulation volume Sᵥ to the simulation area g. The present disclosure enables the reduction of the number of simulation events while maintaining a high event density in the simulation area g. As a result, simulation time can be saved.

Therefore, there is a need to improve a computer-implemented method for simulating energy filtered ion implantation.

### SUMMARY

According to a first aspect of the present disclosure a computer-implemented method for the simulation of an energy-filtered ion implantation is provided, the method comprising the steps of: Determining at least one part of an energy filter; Determining a simulation area in a substrate; Defining an ion tunnel for receiving ions of the ion beam source; Implementing of the determined at least one part of the energy filter, the ion beam source, the determined simulation area in the substrate, the determined ion tunnel in a simulation environment; determining a minimum distance between the implemented at least one part of the energy filter and the implemented substrate for enabling a desired degree of lateral homogenization of the energy distribution in a doping depth profile of the substrate; and defining a total simulation volume Sᵥ. Therefore, the geometrical dimensions of the filter model in the simulator by defining the ion tunnel are minimized and thus the ratio of total simulation volume to simulation area in the substrate is optimized. The desired degree of lateral homogenization is an average deviation of the profiles parallel to the ion beam along the z or y direction, i.e. along the substrate surface, of less than 10% or 5% or 3%. The step of implementing approximated geometrical dimensions of the energy filter comprises the using of an analytical mathematical description of the energy filter or/and using a meshing description. The advantage of the present disclosure results from the improved ratio of total simulation volume Sᵥ to the simulation area g, which allows a reduction of simulation events, compared to the conventional model, while maintaining the same event density of the simulation area g. This has a positive effect on simulation durations, hardware, resources and energy consumption.

In one aspect of the method, at least one part of a filter unit cell of the energy filter is defined as the least one part of the energy filter. The filter unit cell is defined as the fraction of an energy filter, which represents the entire energy—and angular spectrum of a particular energy filter. Several unit cells can be added to form an energy filter in reality.

In one aspect of the method, the simulation environment is a Monte-Carlo simulation environment.

In one aspect of the method, the dimensions in the z-y plane of the ion tunnel are defined such that those ions that reach a first edge of the defined total simulation area are reintroduced on the other edge of the defined total simulation area.

In another aspect of the method, the ion tunnel is defined such those ions from the first edge of the defined total simulation area are shifted within the y-z plane to the opposite edge of the defined total simulation area.

In another aspect of the method, the at least one part of the energy filter is defined such that the at least one part of the energy filter is at least half of a filter unit cell.

In one aspect of the method, the ion tunnel is defined such that the ion tunnel must have at least the same dimensions as the determined simulation area.

In another aspect of the method, the ion tunnel is defined such that the tunnel must have at least the same dimensions as the filter unit cell or multiples of the filter unit cell.

In one aspect of the method, a required dimension of the simulation area in the substrate is determined by a simulation task.

In one aspect of the method, the required dimension of the simulation area in the substrate is determined by the dimension of a masking structure on the substrate.

In one aspect of the method, the method further comprises the step of implementing approximated geometrical dimensions of triangular-shaped, pyramid-shaped, inverted pyramid-shaped, or free-form shaped energy filters and/or supporting structures.

In one aspect of the method, the method further comprises the step of implementing approximated geometrical dimensions of the filter unit cells composed of several base elements of different geometry, different material composition or different layer structure.

In one aspect of the method, the method further comprises the step of tilting of the energy filter.

In one aspect of the method, the method further comprises the step of mirroring the ion beam about an axis perpendicular to the ion beam by a mirror in the ion tunnel.

In one aspect of the method, the method further comprises the step of superposition of several simulations with different primary energies, ion types or angles of incidence of the primary ions.

### DESCRIPTION OF THE FIGURES

The present disclosure will now be described on the basis of figures. It will be understood that the aspects and aspects of the present disclosure described in the figures are only examples and do not limit the protective scope of the claims in any way. The present disclosure is defined by the claims and their equivalents. It will be understood that features of one aspect or aspect of the present disclosure can be combined with a feature of a different aspect or aspects of other aspects of the present disclosure. This present disclosure becomes more obvious when reading the following detailed descriptions of some examples as part of the disclosure under consideration of the enclosed drawings, in which:

FIG. 1 shows the principle of the ion implantation device with an energy filter based on related art.

FIG. 2A shows a structure of the ion implantation device with the energy filter.

FIG. 2B shows the typical installation of an energy filter in a system for ion implantation for the purpose of wafer processing, with movable substrate.

FIGS. 3A and 3B show the typical installation of an energy filter in a system for ion implantation for the purpose of wafer processing.

FIGS. 4A to 4D show three-dimensional structures of filters illustrating the principal possibilities of using energy filters to generate a large number of doping depth profiles.

FIG. 5A shows the schematic illustration of a unit cell of a filter structure.

FIG. 5B shows the cross-sectional view of FIG. 5A in the y-z plane of a static irradiation situation of an energy filter, ion source and a substrate.

FIG. 6A shows an arrangement such that an energy filter is in contact with a substrate.

FIG. 6B shows an arrangement of an energy filter and a substrate with “sufficient” distance.

FIGS. 7A to 7C show a filter and substrate spaced 20 μm, 500 μm, and 3000 μm apart.

FIG. 8 shows a schematic illustration of a static simulation model according to one aspect of the present disclosure to reduce the total simulation volume Sᵥ by the implementation of an ion tunnel, in which the ions at the edges of the ion tunnel are mirrored in the y-z plane to the center of the x-axis.

FIG. 9 shows a flowchart of the method according to the present disclosure.

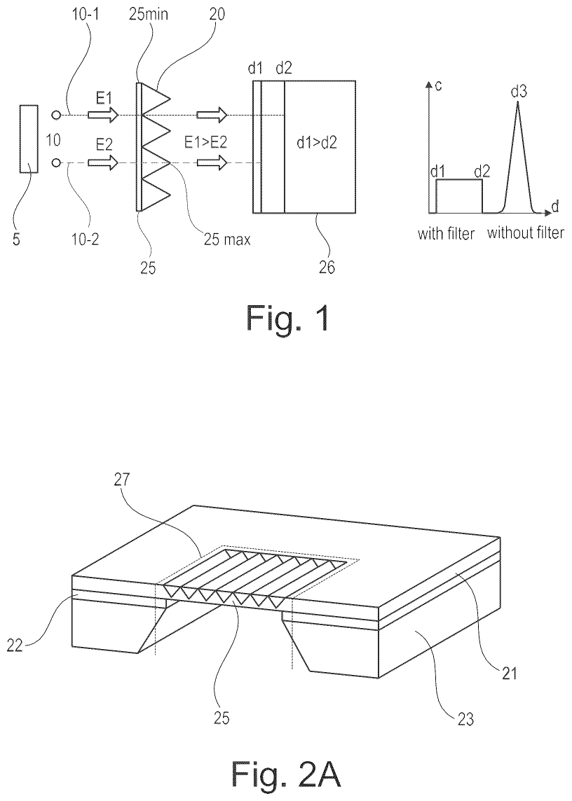

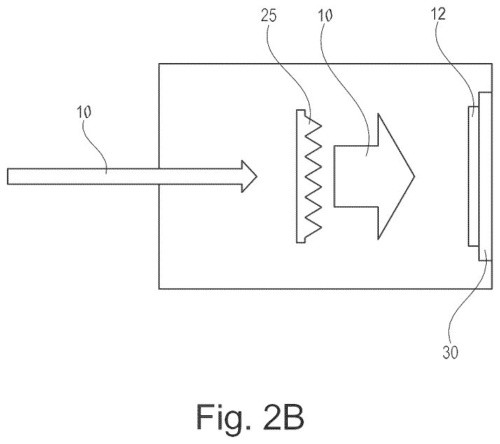

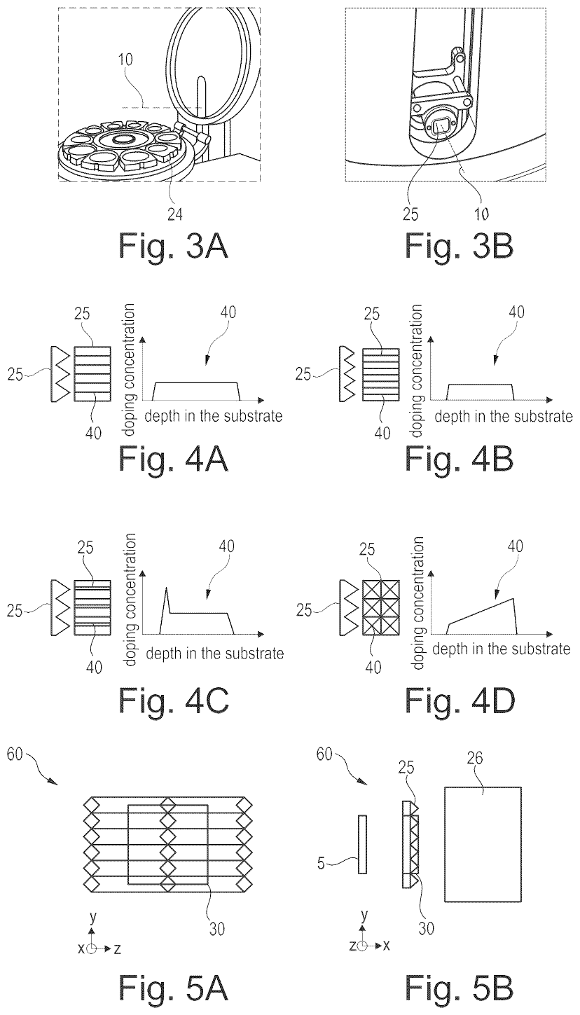

### DETAILED DESCRIPTION

FIG. 8 shows a schematic illustration of a static computer simulation model according to one aspect of the present disclosure for simulating doping depth profiles 40 in a simulation model to reduce a total simulation volume Sᵥ by the implementation of an ion tunnel 70, in which the ions 10 at the edges of the ion tunnel 70 are mirrored in the y-z plane to the center of the x-axis.

The task of simulating dopant depth profiles 40 comprises two subtasks: a first sub task of calculating the energy and angular distribution after the ions 10 have passed through the energy filter 25; and a second subtask of determining the effect of ions 10 acting on the substrate 26 with this calculated energy and angular distribution.

As can be seen in FIG. 8, the computer simulation model is simplified by using the ion tunnel 70. The method according to the present disclosure is provided for implementing the energy-filtered ion implantation (EFII) process in, for example, a Monte Carlo, environment.

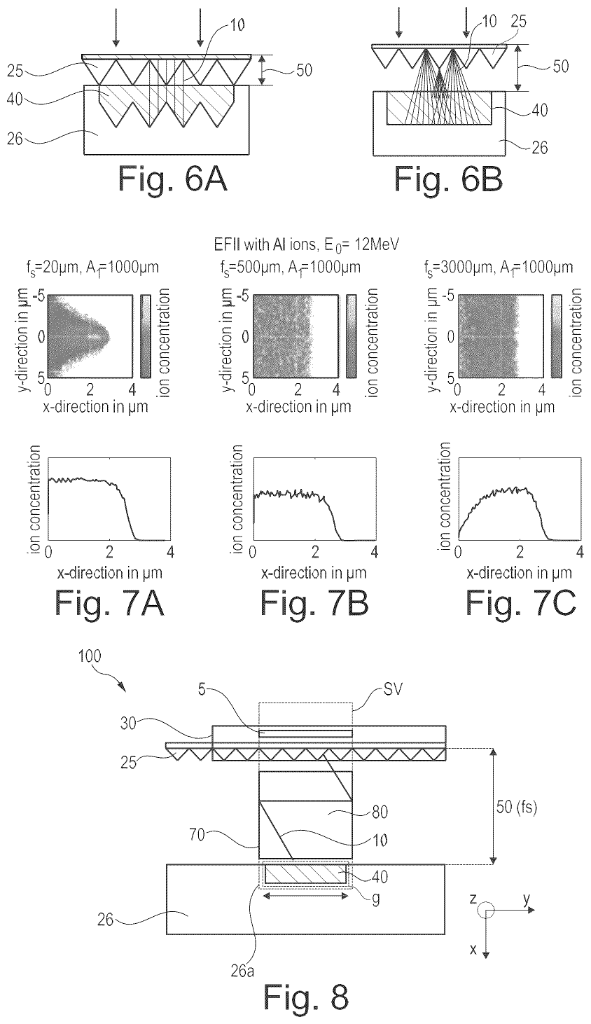

As can be seen in FIG. 8, a narrower width of the energy filter 25, the ion source 5 and the substrate 26 is defined as the total simulation Sᵥ volume (see dotted line in FIG. 8) instead of the whole filter width, e.g., for irradiation of a six-inch (15.54 cm) wafer. In order to obtain correct simulation results, the ions 10 which reach the (e.g., right) edge of the simulation area g are reintroduced on the left side. In this ion tunnel 70, those ions 10 are thus shifted from one edge of the ion tunnel 70 within the y-z plane to an opposite edge of the ion tunnel 70. As can be seen in FIG. 8, distance (fs) 50 between the energy filter 25 and the substrate 26 must be selected in such a way that the distance 50 meets the described requirements according to the application. These requirements are for most applications a desired degree of lateral homogenization, i.e., less than 10%, less than 5%, less than 3%. However, there are applications where a site-dependent depth profile of the dopant or implantation defects or energy deposition is desired or where a y-z position-dependent depth profile of the dopant or implantation defects or energy deposition is desired. This can go from perfect structure transfer (in contact, see FIG. 6A) through any intermediate steps to perfect homogenization, see FIG. 6B. With regard to the EFII process, this distance 50 is the minimum distance that leads to a desired degree of lateral homogenization of the energy distribution. The desired degree of lateral homogenization is an average deviation of the profiles parallel to the ion beam along the z or y direction. i.e., across the substrate surface, of less than 10% or 5% or 3%.

As can be seen in FIG. 8, due to the mirroring of the ions 10 in the ion tunnel 70 by the mirror 80, there is no loss of the scattered ions 10 with a large scattering angle outside the ion tunnel 70, of the characteristic energy spectrum of the energy filter 25 at the end of the ion tunnel 70 in the substrate 26. The total simulation volume Sᵥ (see dotted line) results from the necessary dimensions of the simulation area g (see dashed line) as well as from the dimensions of the energy filter 25, which correspond to at least half a filter unit cell 30. The filter unit cell 30 is defined as the fraction of the energy filter 25, which represents the entire energy and angular spectrum of a particular energy filter 25. Several ones of the unit cells 30 will be added to form an energy filter 25 in reality. The ion tunnel 70 must have at least the dimensions of the simulation area g or must have at least the width of one (or half) filter unit cell 30. Further, the ion tunnel 70 must also always consist of integer multiples of the minimum filter unit cell 30. The required dimension of the simulation area g on the substrate 26 results from the application to be simulated, e.g., in case of an implantation into a masking structure on the substrate 26. The dimension of the masking structure will therefore define the extent of the simulation area g.

One example uses the implantation parameters of 12 MeV as a primary energy, the distance 50 (fs)=500 μm, a common filter unit cell 30 dimension of ≈5-50 μm, and the simulation area g=2 μm, the ratio of total simulation volume Sᵥ to the simulation area g is g/Sᵥ≈10-4%, wherein g is the simulation area and Sᵥ is the total simulation volume.

It will be appreciated that the present simulation is not limited to triangular-shaped filter unit cells 30. Rather, pyramidal, inverted pyramidal, or more generally free-form structures or supporting structures can also be simulated using the computer-implemented method 200 of the present document. It should be noted that more complex energy filters 25 can also be simulated using the method 200. For example, a filter unit cell 30 can be composed of several basic elements of different geometry, different material composition or different layer structure. Tilting of the energy filter 25 or mirroring about an axis perpendicular to the ion beam 10 is also possible. Furthermore, the superimposition of several simulations with, for example, different primary energies, ion types or angles of incidence of the primary ions is conceivable.

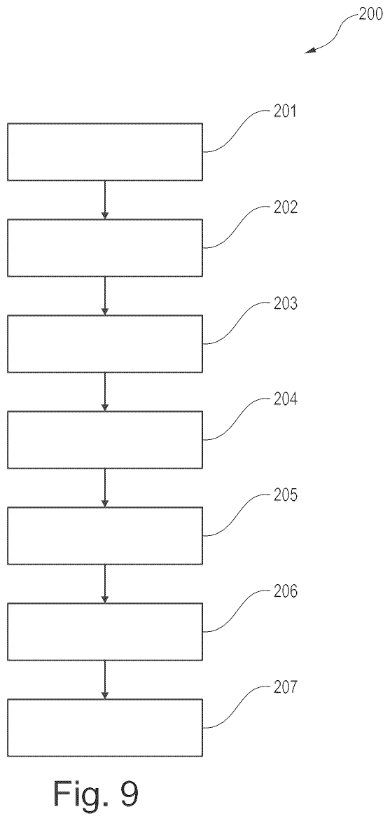

FIG. 9 shows a flowchart of the computer-implemented method 200 according to the present description. The computer-implemented method 200 for the simulation of an energy-filtered ion implantation (EFII) comprises a step of determining 201 at least one part of an energy filter 25 as an input parameter for the simulation model. The at least one part of an energy filter 25 can be at least one filter unit cell 30, which is defined as the fraction of an energy filter 25 representing the entire energy and angular spectrum of the particular energy filter 25. Several ones of the filter unit cells 30 can be added to form an energy filter 25 in reality. Therefore, the approximated geometrical dimensions of at least one part of the energy filter 25 are determined in step 201. For example, an approximated geometrical dimension of the filter unit cell 30 of the energy filter 25 is implemented in step 201 in a simulation environment. However, the present disclosure is not limited thereto and approximated geometrical dimensions of a plurality of filter unit cells 30 of the energy filter 25 can be implemented in step 201.

Further, the method 200 comprises the step of determining 202 the simulation area g in the substrate 26 as a further input parameter for the simulation model. For example, the simulation area g in the substrate 26 is the laid-out structure. Further, the method 200 comprises the step of defining 203 the ion tunnel 70 for receiving the ions 10 of the ion beam source 5. The step of defining 203 comprise a step in which the ion tunnel 70 is defined in a z-y plane for receiving the ions 10 from the ion beam source 5. Therefore, the width of the ion tunnel 70 is defined and the energy filter 25 and the ion tunnel 70 is implemented. The ion tunnel 70 is either defined by the definition by the application, e.g., a certain layout structure (i.e. simulation area g); the minimum extent of the filter unit cell 30, so that at least the entire angular and energy spectrum is emitted.

The area of the ion tunnel 70 in the z-y plane must be decomposable into integer multiples of the filter unit cell 30. Therefore, the method 200 comprises the step of implementing 204 the determined at least one part of the energy filter 25, the ion beam source 5, the determined simulation area g in the substrate 26, and the defined ion tunnel 70 in a simulation environment. The implementing step 204 implements the approximated geometrical dimensions of the energy filter 25, the ion beam source 5, the substrate 26, the simulation area g, and the ion tunnel 70 in the simulation environment. The input parameters for the simulation model are thereby defined and implemented. After defining and implementing the input parameters for the simulation model, the method 200 comprises the step of determining 205 a minimum distance 50 between the energy filter 25 and the substrate 26 for enabling a desired degree of lateral homogenization of the energy distribution in a doping depth profile of the substrate 26. The minimum distance 50 between the energy filter 25 and the substrate 26 is determined either by at least one of an experiment, a regression simulation (trying out several distances), or a mathematical calculation.

For the determining step 205 of the minimum distance 50, for example, a minimal filter unit cell 30, i.e., the minimal part of the energy filter 25 representing the complete energy and angle spectrum, is implemented in the simulator and simulates the angular distribution. For the determining step 205 of the minimum distance 50, in another example, a plurality of filter unit cells 30 are implemented in the simulator and simulates with a first guess distance. Then the result is analyzed with respect to a desired degree of lateral homogenization and the distance is iteratively changed until the homogenization criterion is fulfilled (e.g., average deviation from profile to profile is less than 5%). Alternatively, for the determining step 205 of the minimum distance 50, for example, data from experiments or a database can be used. The method 200 is not limited to the particular order/sequence of the steps 201, 202, 203, 204 and 205.

The method 200 further comprises the step of defining 206 the total simulation volume Sᵥ. The step of defining 206 comprises the defining of the total simulation volume Sᵥ by defining a narrower width of the energy filter (25), a narrower width of the ion beam source (5), and a narrower width of the substrate (26). Therefore, the method 200 is carried out such that firstly the minimum energy filter size (e.g. filter unit cell 30) is determined in step 201 and at the same time the simulation area g is determined in step 202. From this, after implementation of the input parameter, the size of the ion tunnel 70 is defined in step 204. Independently of the steps 201, 202, 203 and 204, the minimum distance 50 is determined in step 205. Then the minimum energy filter size, simulation area g, the ion tunnel 70, and the minimum distance 50 are merged resulting in the simulation of an energy-filtered ion implantation (EFII). The geometrical dimensions of the filter model in the simulator by defining the ion tunnel 70 are minimized and thus the ratio of total simulation volume Sᵥ to simulation area g in the substrate 26 is optimized.

The desired degree of lateral homogenization is an average deviation of the profiles parallel to the ion beam 10 along the z or y direction, i.e., across the substrate surface of the substrate 26, of less than 10% or 5% or 3%. The advantage of the disclosure results from the improved ratio of total simulation volume Sᵥ to the simulation area g, which allows a reduction of simulation events, compared to the conventional model, while maintaining the same event density of the simulation area g. This has a positive effect on simulation durations, hardware, resources and energy consumption. The method 200 further comprises the step of executing 207 the simulation.

The simulation environment can for example be a Monte Carlo simulation environment. The ion tunnel 70 is defined such that the ions 10 which reach a first edge of the determined total simulation volume Sᵥ are reintroduced on the other edge of the determined total simulation volume Sᵥ. The ion tunnel 70 is defined such the ions 10 from the first edge of the determined total simulation volume Sᵥ are shifted within the y-z plane to the opposite edge of the determined total simulation volume Sᵥ. The narrower width of the energy filter 25 is defined such that the narrower width of the energy filter 25 is at least half of a filter unit cell 30. The ion tunnel 70 is defined such that the ion tunnel 70 must have at least the same dimensions as the determined simulation area g. The required dimension of the simulation area g of the method 200 in the substrate 26 is determined by the simulation task. The required dimension of the simulation area g in the substrate 26 is determined by the dimension of, for example, a masking structure 26a on the substrate 26.

The method 200 further comprises the step of implementing approximated geometrical dimensions of triangular-shaped, pyramid-shaped, inverted pyramid-shaped, or free-form shaped energy filters 25. The step of implementing approximated geometrical dimensions of the energy filter comprises the using of an analytical mathematical description of the energy filter or/and using a meshing description. The method 200 further comprises the step of implementing approximated geometrical dimensions of filter unit cells 30 composed of several base elements of different geometry, different material composition or different layer structure. The method 200 further comprises the step of tilting of the energy filter 25 with respect to the ion beam 10. The method 200 further comprises the step of mirroring the ion beam 10 about an axis perpendicular to the ion beam 10 by a mirror 80 in the ion tunnel 70.

The method 200 further comprises the step of superposition of several simulations with different primary energies, ion types or angles of incidence of the primary ions.

1. A computer-implemented method for the simulation of an energy-filtered ion implantation, comprising the steps of:
determining at least one part of an energy filter;
determining a simulation area in a substrate;
defining an ion tunnel for receiving ions directed from an ion beam source;
implementing the determined at least one part of the energy filter, the ion beam source, the determined simulation area in the substrate, and the defined ion tunnel in a simulation environment;
determining a minimum distance between the implemented at least one part of the energy filter and the implemented substrate for enabling a desired degree of lateral homogenization of the energy distribution in a doping depth profile of the implemented substrate; and
defining a total simulation volume.

2. The method of claim 1, wherein at least one filter unit cell of the energy filter is defined as the least one part of an energy filter.

3. The method of claim 1, wherein the simulation environment is a Monte Carlo simulation environment.

4. The method of claim 1, wherein the ion tunnel is defined such that the ions which reach a first edge of the determined total simulation volume are reintroduced on the other edge of the defined total simulation volume.

5. The method of claim 1, wherein the ion tunnel is defined such the ions from the first edge of the defined total simulation volume are shifted within the y-z plane to the opposite edge of the determined simulation total simulation volume, wherein the y-z plane is parallel to a surface of the substrate.

6. The method of claim 2, wherein the at least one part of the energy filter is defined such that the at least one part of the energy filter is at least half a width of the filter unit cell, wherein the width of the filter unit cell is measured in a direction parallel to a y-z plane, and wherein the y-z plane is parallel to a surface of the substrate.

7. The method of claim 1, wherein the ion tunnel is defined such that the ion tunnel has at least the same dimensions as the determined simulation area.

8. The method of claim 2, wherein the ion tunnel is defined such that the tunnel must have at least the same dimensions as the filter unit cell or multiples of the filter unit cell.

9. The method of claim 1, wherein a required dimension of the simulation area in the substrate is determined by a simulation task.

10. The method of claim 9, wherein the required dimension of the simulation area in the substrate is determined by the dimension of a masking structure on the substrate.

11. The method of claim 1, further comprising implementing approximated geometrical dimensions of triangular-shaped, pyramid-shaped, inverted pyramid-shaped, or free-form shaped energy filters.

12. The method of claim 1, further comprising implementing approximated geometrical dimensions of filter unit cells composed of several base elements of different geometry, different material composition or different layer structure.

13. The method of claim 1, further comprising tilting of the energy filter.

14. The method of claim 1, further comprising mirroring the ion beam about an axis perpendicular to the ion beam by a mirror in the ion tunnel, wherein the ion beam is mirrored in a/the direction parallel to a/the y-z plane, and wherein the y-z plane is parallel to a/the surface of the substrate.

15. The method of claim 1, further comprising superposition of several simulations with different primary energies, ion types or angles of incidence of the primary ions.
